(19) United States
(12) Patent Application Publication
(10) Pub. No.: US 2008/0174314 A1
(43) Pub. Date: Jul. 24, 2008

(54) MULTI-CHANNEL COIL FOR MAGNETIC RESONANCE IMAGING

(76) Inventors: Joshua J. Holwell, Plymouth, MN (US); Scott M. Schillak, Minneapolis, MN (US); Kenneth M. Bradshaw, Chaska, MN (US); Brandon J. Tramm, Eden Prairie, MN (US); Labros L. Petropoulos, Auburn, OH (US)

Correspondence Address: INTELLECTUAL PROPERTY GROUP;FREDRIKSON & BYRON, P.A., 200 SOUTH SIXTH STREET, SUITE 4000, MINNEAPOLIS, MN, 55402, US

(21) Appl. No.: 11/943,238

(22) Filed: Nov. 20, 2007

Related U.S. Application Data
(60) Provisional application No. 60/867,132, filed on Nov. 24, 2006.

(51) Int. Cl. G01R 33/34; G01R 33/48

(52) U.S. Cl. 324/318

(57) ABSTRACT

This document discusses, among other things, a system and method for a coil having a plurality of resonant elements capable of radiofrequency transmission, reception, or both transmission and reception. One example includes a multi-channel receive-only coil comprised of overlapping planar loops. Adjacent resonant elements are decoupled from one another by both capacitive elements and by the geometric configuration of the elements. Cables are coupled to each resonant element and are gathered at a junction in a particular manner.

### PRIORITY CLAIMED

This application claims priority under 35 U.S.C. §119(e) to U.S. Ser. No. 60/867,132, filed Nov. 24, 2006, which is hereby incorporated in its entirety by reference thereto.

### TECHNICAL FIELD

This document pertains generally to a magnetic resonance coil, and more particularly, but not by way of limitation, to a magnetic resonance coil with multiple channels.

### BACKGROUND

Magnetic resonance imaging and magnetic resonance spectroscopy involve providing an excitation signal to a specimen and detecting a response signal. The excitation signal is delivered by a transmit coil and the response is detected by a receive coil. In some examples, a single structure is used to both transmit the excitation signal and to receive the response.

Known devices and methods are inadequate.

### BRIEF DESCRIPTION OF THE DRAWINGS

In the drawings, which are not necessarily drawn to scale, like numerals describe substantially similar components throughout the several views. Like numerals having different letter suffixes represent different instances of substantially similar components. The drawings illustrate generally, by way of example, but not by way of limitation, various embodiments discussed in the present document.

FIGS. 1A and 1B include sectional views of exemplary resonant elements.

FIG. 2 includes a perspective view of a coil.

FIG. 3 includes a model of two resonant elements.

FIG. 4A illustrates a perspective view of an exemplary coil.

FIG. 4B is a schematic of an exemplary resonant element pattern.

FIG. 4C is a detailed view of the schematic of FIG. 4B.

FIG. 4D illustrates the imaging area of an exemplary coil.

FIG. 5 illustrates a perspective view of an exemplary coil.

FIG. 6 illustrates an electrical system for an exemplary coil.

FIG. 7 illustrates a model of two resonant elements.

FIG. 8 illustrates a side view of a coil.

FIG. 9 illustrates a perspective view of a coaxial bundle.

FIGS. 10A, 10B and 10C illustrate variable impedances.

FIGS. 11A and 11B illustrate a curved row of resonant elements.

FIG. 12 includes a volume coil having a curved profile.

FIG. 13 includes a segment of a flexible material having a plurality of resonant elements.

FIG. 14 includes an exemplary coil for breast imaging.

FIG. 15 illustrates an exemplary housing for a coil of the present subject matter.

### DETAILED DESCRIPTION

The following detailed description includes references to the accompanying drawings, which form a part of the detailed description. The drawings show, by way of illustration, specific embodiments in which the invention may be practiced. These embodiments, which are also referred to herein as “examples,” are described in enough detail to enable those skilled in the art to practice the invention. The embodiments may be combined, other embodiments may be utilized, or structural, logical and electrical changes may be made without departing from the scope of the present invention. The following detailed description is, therefore, not to be taken in a limiting sense, and the scope of the present invention is defined by the appended claims and their equivalents.

In this document, the terms “a” or “an” are used, as is common in patent documents, to include one or more than one. In this document, the term “or” is used to refer to a nonexclusive or, unless otherwise indicated. Furthermore, all publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

The present subject matter relates to one or more coils for magnetic resonance imaging and spectroscopy. In one example, a multi-channel receive-only coil is combined with a single channel transmit coil for magnetic resonance imaging. Another example includes the use of multiple receive-only coils. In one example, a coil includes decoupling capacitors associated with discrete resonant elements of the coil. The decoupling capacitors provide a capacitance value that is a function dependent on proximity to an adjacent resonant element. In one example, a sixteen element knee coil, in the form of a volume coil, uses transmission line technology configured for parallel imaging. In addition to a knee coil, the present subject matter can be tailored for use as a head coil, breast coil, body coil or other type of coil.

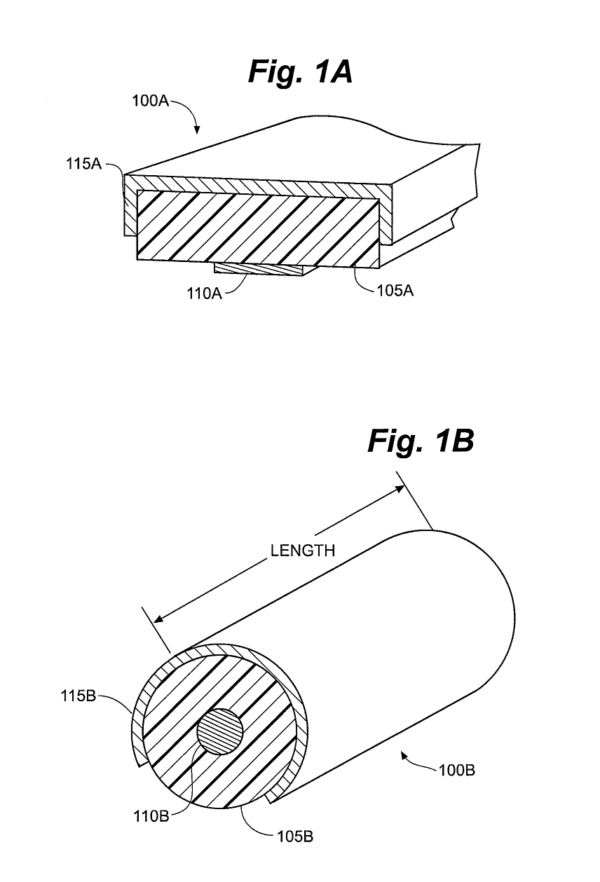

FIGS. 1A and 1B illustrate sectional views of resonant elements according to the present subject matter. A resonant element is an elongate member configured for radio frequency transmission, reception or both transmission and reception. In one example, the resonant element includes a transmission line or other resonant structure having a ground plane and an inner conductor. Resonant element 100A of FIG. 1A illustrates inner conductor 110A and ground plane 115A separated by dielectric 105A. The ground plane can be of planer, faceted, curved or arced cross-section and is of conductive material. Exemplary inner conductors include a center wire on a coaxial line and a single strip of conductive material on a surface of a strip transmission line. The term inner relates to the generally interior portion of the volume coil for which the resonant element is a part. With respect to the generally interior portion, the ground plane is disposed on the exterior portion of the volume coil. Ground plane 115A is disposed on three sides of dielectric 105A and partially encircles inner conductor 110A. Resonant element 100B of FIG. 1B illustrates inner conductor 110B and ground plane 11513 separated by dielectric 105B. Resonant element 100B includes a coaxial line having a portion of an insulative ground removed however, other embodiments include a coaxial line with an insulative ground (shield) fully encircling inner conductor 110B. The length of resonant element 100E is indicated in the figure.

In one example, a resonant element includes a waveguide having a cavity in which radio frequency resonance can be established. Other resonant elements are also contemplated. For example, one coil implements an array of planar loops. The elements of the coil provide, in various embodiments of the present subject matter, improved imaging performance, improved radio frequency transmit efficiency and improved signal-to-noise ratio.

A multi-element coil, or array system, according to the present subject matter, is particularly suited for use in a high field application. Each element, or resonant element, corresponds to a channel and each channel, in one example, is operated independent of other channels. In various examples, the array system can be used for radio frequency transmission, reception or both transmission and reception.

A coil with multi-channel transmit capability for independent phase and amplitude control of its elements can be used for radio frequency shimming to mitigate sample-induced radio frequency non-uniformities. Such an array can be used as a transmitter for parallel imaging and can be combined with receive-only arrays by using preamplifier decoupling for the coils during signal reception. In one example, a 32-element radially configured transmit array head coil is based on transmission line elements operating at high frequencies. Such an array provides electromagnetic decoupling, avoids resonance peak splitting and maintains transmit efficiency. Strong coupling between the sample, or specimen, and the coil at high RF frequencies, complicates equalizing of individual resonance elements performance for different subjects and varying specimen or head positions in the RF coil array.

For a linear transmission line element, sensitive points for lumped element decoupling options are capacitors between neighboring elements at the feed ends of the conductor strips. In this way, a fraction of the feed current with the proper phase can be diverted into the neighboring resonance element to compensate for mutual inductance. Decoupling capacitors between immediate neighboring transmission lines can provide array element decoupling between any two array elements.

A decoupling network for a fixed geometry coil may be configured once and may remain suitable indefinitely. In various examples, the decoupling network includes at least one capacitor, at least one inductor or both capacitors and inductors. In one example, a patch capacitor allows for either linear or non-linear adjustment of the decoupling capacitance depending on the resonance element distance and geometry. Geometric decoupling is provided in other examples by overlapping portions of adjacent planar loops or positioning resonant elements in transverse or orthogonal positions. In one example, a 16-element decoupled receiver array provides parallel imaging at 3 Tesla.

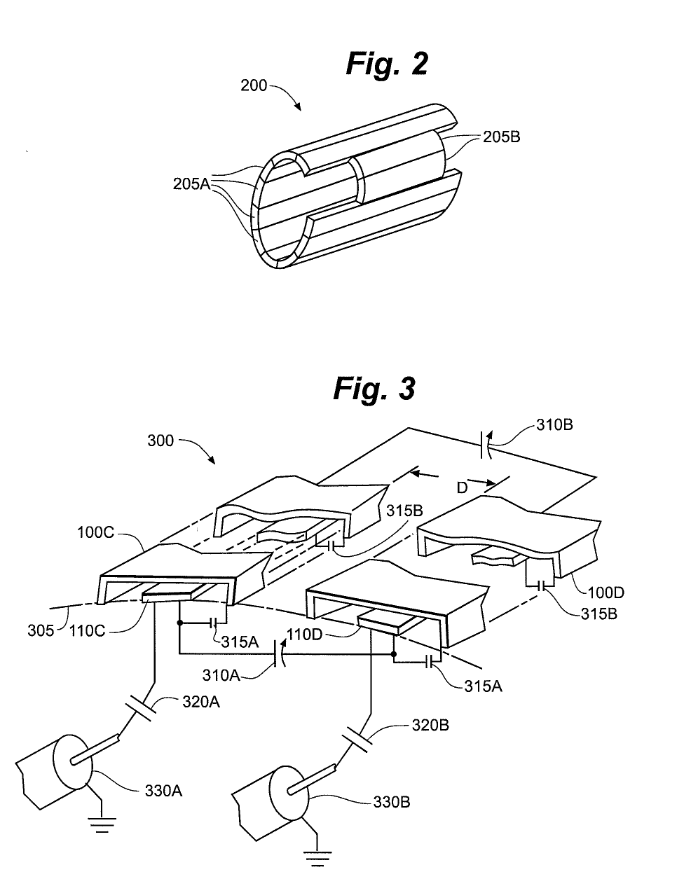

An exemplary coil includes 16-channels that are transmission line arrays (coils) of various configurations. FIG. 2 illustrates one embodiment in which coil 200 includes 12-channels. In the example illustrated in the figure, openings in the coil are provided by the combination of shorter resonant elements 205B and longer resonant elements 205A (8 cm and 14 cm, respectively), configured in the form of a volume coil. The short resonant elements provide access to reduce claustrophobic effects of the coil on a subject and also provides access for viewing or manipulating objects located in the interior of the coil. For the example illustrated, the coil size may be between a minimum interior size of 17 cm by 21 cm and a maximum interior size of 21 cm by 25 cm. Coils having a number of channels greater or fewer than twelve and sixteen are also contemplated, including, for example, a 32-channel coil. In one example, a 64-channel coil includes 64 resonant elements arranged in sixteen rows of four resonant elements per row with each resonant element decoupled from an adjacent resonant element. In one example, at least one resonant element of a coil has a fixed or adjustable curvature to allow conformance to a curved contour of a sample. In various examples, one or more resonant elements are of a length different from that of another resonant element.

In one example, a coil has two short resonant element (10 cm) and fourteen longer resonant elements (14 cm), also in the form of a volume coil. In one example, the interior diameter of the coil approximately 25 cm.

The resonance elements are fabricated of adhesive-backed copper tape (3M, Minneapolis, Minn.) and dielectric material having dimensions of, for example, 4 cm by 1.2 cm by 18 cm. The dielectric material is an insulating polymer such as a fluorinated polymer, PTFE, PFA, tetrafluoroethylene, polytef (polytetrafluoroethylene) or a fluorocarbon resin (FEP—Fluorinated ethylene-propylene or TFE—Tetrafluoroethylene). In other examples, resonant elements of a receive-only coil may take the form of planar loops placed around a non-conducting surface, for example, the exterior surface of a former. In one example, the capacitors, including the variable tune and match capacitors (NMNT 12-6, Voltronic, N.J., USA) and high voltage ceramic chip capacitors (100E series, American Technical Ceramics, NY, USA) are embedded into the dielectric and shielded (covered by a metal foil) to minimize E-field exposure.

In one example, the ground conductor for each resonant element is 4 cm wide and electrically isolated from adjacent elements. To further improve adjacent element decoupling, the ground plane is extended to partially cover the sides of the dielectric material as shown in FIG. 1A. In other examples, the ground plane of a resonant element partially encircles the center conductor as shown in FIG. 1B. Such a configuration reduces coupling with adjacent resonant elements and enhances decoupling, thus enhancing the E-field.

To create an opening in a side (for example, at the front of the face), one or more resonant elements are truncated or shortened as shown in FIG. 2. In the example illustrated, the resonant elements are 8 cm in length. The effective electrical length of the remaining resonance elements is 15 cm.

In one example, capacitors are coupled between adjacent resonant elements to provide decoupling, as show in FIG. 3. In some examples, the capacitance of the capacitors varies according to geometrical distance between resonant elements. These capacitors are variously referred to as a patch capacitor. In one example, the capacitive values for decoupling capacitors are in the range of 2.5 pF±1 pF. Other decoupling capacitance values are also contemplated. In some examples, the decoupling capacitors are high voltage capacitors, which may have a fixed capacitance.

FIG. 3 illustrates electrical circuit diagram 300 associated with two exemplary resonant elements in adjacent configuration. The resonant elements have ground planes 100C and 100D and are shown to partially encircle inner conductors 110C and 110D, respectively. The resonant elements lie on curvature 305 and are held in position by a rigid or flexible frame (not shown). Tuning capacitors 315A and 315B are illustrated at each end of the resonant elements and are coupled between the inner conductors 100C and 110D and ground planes 100C and 100D, respectively. Tuning capacitors 315A and 315B are selected to provide sensitivity at a particular resonant frequency. Decoupling capacitors 310A and 310B (variously referred to as patch capacitors) are illustrated at each end of the resonant elements and are coupled between adjacent ground planes 100C and 100D. Decoupling capacitors 310A and 310B are of variable impedance and in one example of the present subject matter, the value is a function of distance D between the resonant elements. In the example illustrated, two decoupling capacitors are shown, however, in other embodiments, a single capacitor (or impedance device) is used and in other embodiments, more than two impedance devices are provided.

Matching capacitors 320A and 320B are coupled between coaxial lines 330A and 330B, respectively and inner conductors 110C and 110D, respectively.

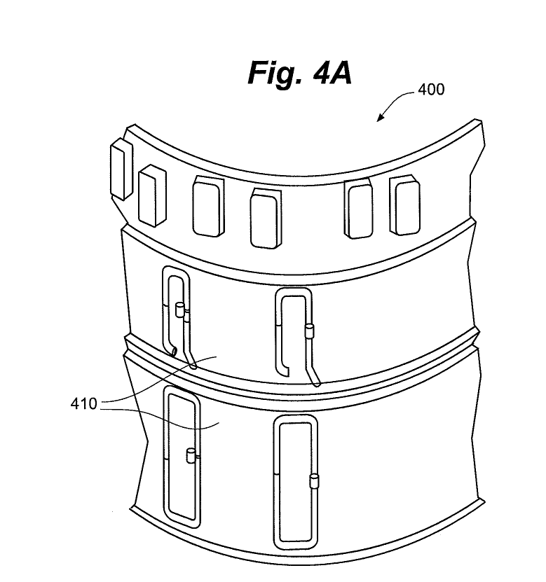

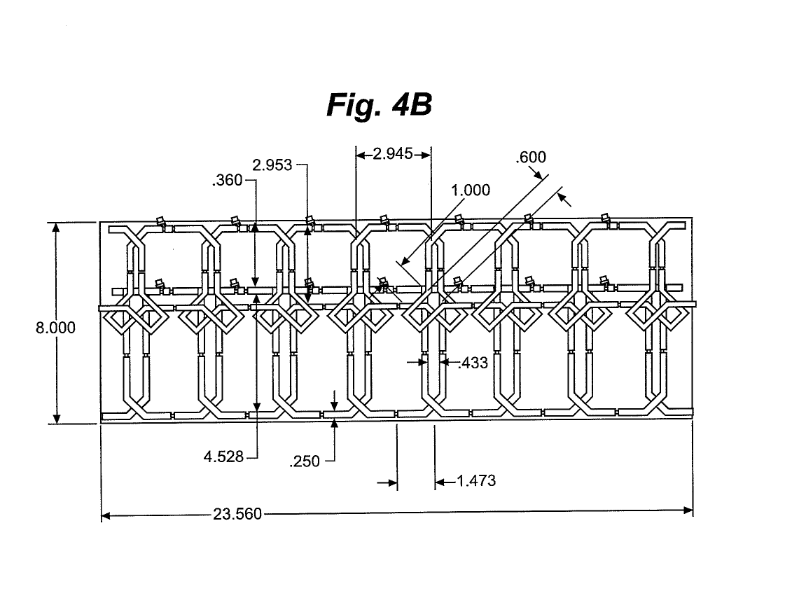

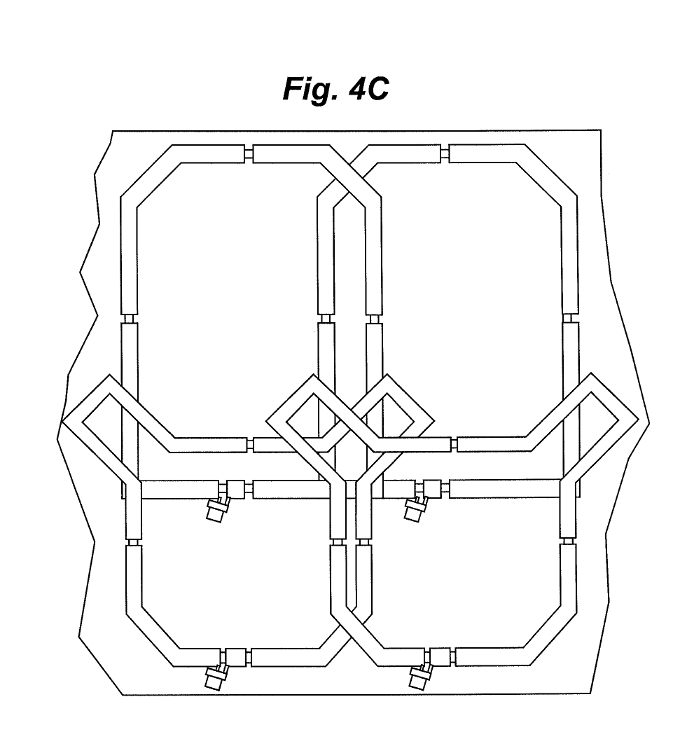

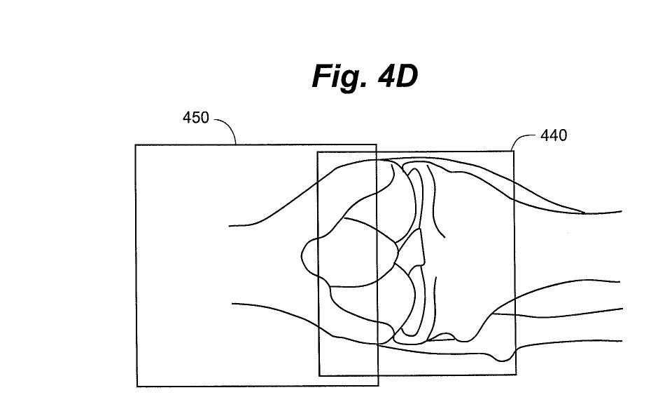

In one example, a coil implements a number of planar loops to provide a multi-channel receive coil. FIG. 4A illustrates coil 400 including a 16 channel planar array disposed on the exterior surface of a cylindrical volume in an 8×2 loop configuration. Loops 410 are disposed around the circumference of the cylindrical volume in order to provide a complete image, for example, a whole knee image. In the example shown, loops 410 are disposed in an overlapping pattern to provide geometric decoupling between adjacent loops. In one example, capacitive elements are also used for decoupling. To reduce the effect of the planar loops during transmit, in some examples passive, active, or both passive and active diode blocking networks are included.

FIG. 4B shows one example of a planar loop array pattern of the present subject matter. The coil pattern includes a configuration of two rows of eight resonant elements, which are disposed circumferentially around the exterior of a nonconductive cylindrical volume. FIG. 4C shows a detailed view of the loop array pattern of FIG. 4B. In the example shown, the corners of adjacent loops 2 and 4 are configured to overlap in order to provide geometric decoupling. In addition, portions of other loops also overlap to provide decoupling.

FIG. 4D shows a representation of two coil loops positioned over a knee. Smaller loop 440 provides a higher SNR in some examples, and so is positioned over the critical imaging area of the knee (i.e., the meniscus). The overlap of coils 440 and 450 provides a larger imaging area than one loop alone, while still providing the higher SNR of a smaller loop for critical imaging.

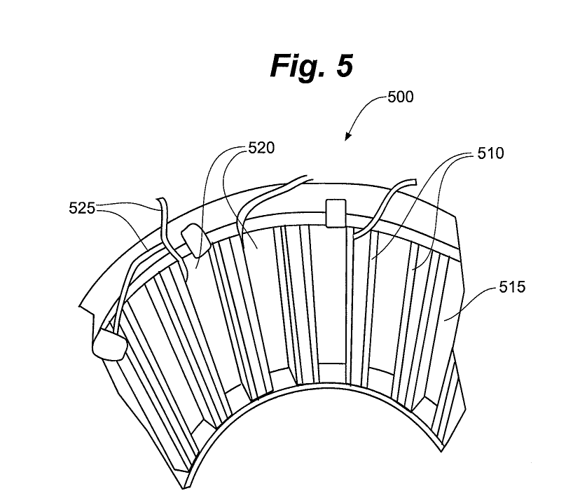

FIG. 5 illustrates one example of a transmit-only coil. Coil 500 is in this example a single-channel volume coil. Inner conductors 510 are circumferentially disposed around the interior of the volume. Each conductor is placed upon a dielectric 515, which separates the conductor from the ground plane 520. In one example, the dielectric is an insulating polymer such as a fluorinated polymer, PTFE, PFA, tetrafluoroethylene, polytef (polytetrafluoroethylene) or a fluorocarbon resin (FEP—Fluorinated ethylene-propylene or TFE—Tetrafluoroethylene). As shown in FIG. 5, the dielectric has dimensions of 0.75 inches thick and 9.5 inches long. Coaxial lines 525 electrically couple the transmit coil to the larger magnetic resonance system. In one example, series diode blocking networks are used to detune the coil during receive.

In one example, a head coil frame allows for patient positioning outside the coil. The frame has a firm portion to support the back of the subjects head. The firm portion includes a 10 cm wide 18 cm long curved section (radius=10 cm) of ¼″ thick plastic. In one example, the plastic includes an acetal resin or homopolymer such as Delrin (Dupont). In one example, the firm holder section is combined with a flexible portion using 1/16″ thick Teflon. The head holder is attached to the table bed and allows for adjustments of the holder height along the y-axis by ±2 cm. In this way, the subject can be centered in the coil based on individual head size. Foam cushion material disposed around the inside of the head holder improves patient comfort and provides a minimal distance of 1.5 cm from the resonance elements. In one example, the coil includes 32 resonant elements and is coupled to a 32-channel digital receiver system.

In one example of the present subject matter, transmit phase increments for each channel of a multi-channel transmit coil can be adjusted for image homogeneity by altering the cable length in the transmit path. The decoupling capacitor patches located between neighboring coils and close to the capacitive feed-points (as shown in FIG. 3 for example) averts RF peak splitting while allowing for coil size changes. In one example, decoupling adjustment can be established for an unloaded coil. A load (such as a spherical phantom of 3 L, 90 mM saline or a human head) primarily dampens next neighbor (resonant element) coupling. The initial value of the variable capacitive patches can be established on a bench using an unloaded coil. In one example, initial decoupling capacitor values (for reducing next neighbor coupling for different coil geometries) were determined experimentally. The values of a capacitor in the decoupling network can be measured with an LCR meter (Fluke 6303A) by electrically isolating the capacitor from the resonance circuitry. The actual decoupling capacitor values can be established by adjustment of the copper width and overlap for the patch capacitors between the resonance elements. In one example, and using various subject head sizes, the array elements are independently tuned and matched from one another for 50Ω match without change of the decoupling capacitor network. In one example, tuning capacitors are disposed at the ends of each transmission line element and the value is adjusted to select a particular resonant frequency. The tuning capacitor is coupled between the inner and outer conductor of the resonant element.

### ADDITIONAL EXAMPLES

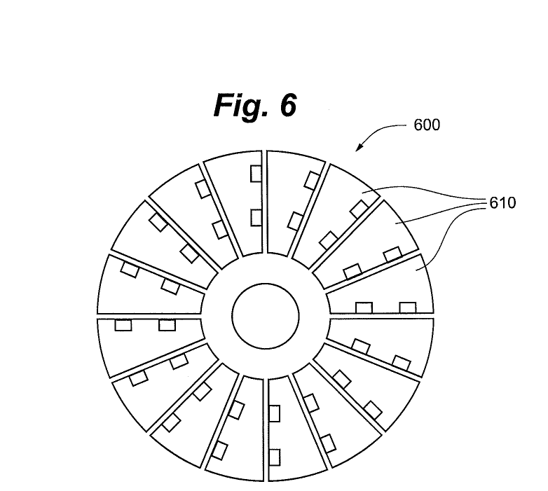

In examples of the present subject matter, signals received by a coil are amplified before being routed to a later stage for processing and analysis. In one example, a preamplifier is provided for each channel in a multi-channel coil. FIG. 6 illustrates an electrical system 600 which includes multiple electronic circuit boards 610. Each circuit board includes a preamplifier for amplifying the signal from an individual channel of a receive coil. In FIG. 6, 32 low input impedance preamplifiers are provided, one for each channel of a 32-channel coil. In some examples, circuit boards 610 also include transmit/receive protection switches and/or preamplifier decoupling networks. Electrical system 600 may in some examples be mounted in a separate structure, which is then mechanically fastened to an end of a receive coil. In other examples, the electrical system is integrated with the receive and/or transmit coil.

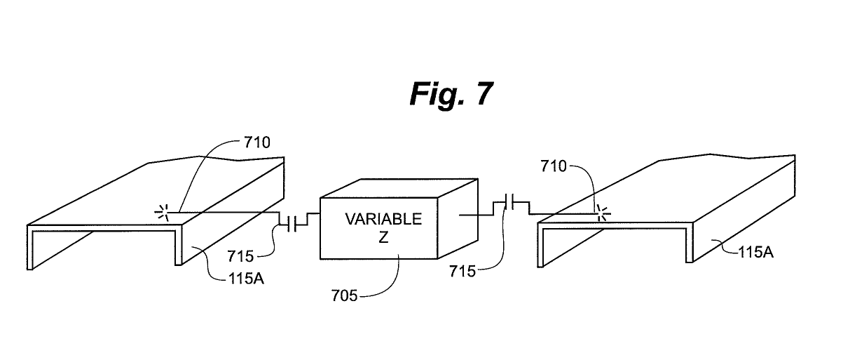

In one example, a variable impedance is coupled between adjacent resonant elements to provide controlled coupling, as shown in FIG. 7. In the figure, ground planes 115A are coupled by variable impedance 705. In some examples, high voltage capacitors 715 are positioned between ground planes 115A and the variable impedance. In other examples, a high voltage capacitor 715 of a fixed value may replace variable impedance 705. Variable impedance 705 is electrically bonded by solder connections 710 through high voltage capacitors 715. Examples of variable impedances include a variable inductor and a variable capacitor. The amount of impedance coupling between adjacent resonant elements can be tailored for a particular situation. For instance, more coupling capacitance may be used when adjacent resonant elements are positioned more closely and less capacitance is used when farther apart.

In general, a coupling capacitor is positioned at a point along the length of the resonant element where the voltage is at a high level, which typically coincides with the endpoints of the resonant elements. In general, a coupling inductor is positioned at a point along the length of the resonant element where the current is at a high level, which typically coincides with the middle of the resonant elements. In various examples, multiple decoupling capacitors or inductors are coupled between selected resonant elements at various locations. For example, a particular coil includes a pair of decoupling capacitors between each resonant element, where each resonant element has a capacitor at each end.

In addition to transmit coils, the present subject matter can be applied to a receive-only array. In one example, a receive-only array (coil) includes a number of short transmission line (resonant) elements and is particularly suited to use at higher frequencies where the relative close RF ground plane has a reduced effect on the overall coil performance. In one example, a closer coil setting can cause some local signal cancellation. The cancellation is a transmit phase effect and can be corrected through RF phase shimming.

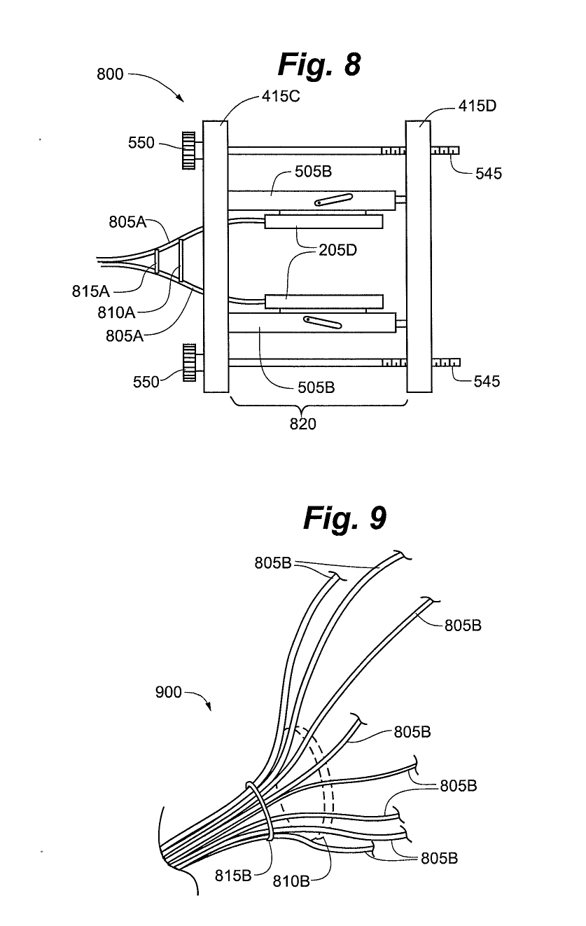

FIG. 8 illustrates another structure for holding resonant elements. A side view shows coil 800 having two resonant elements 205D arranged in a volume coil configuration according to an embodiment with adjustability. Resonant elements 205D are carried by resonant element holders 825 having diagonally aligned slots that engage pins for control of radial position. End plates 855 and 856 are moved relative to each other by means of threaded shaft 845 turned by knob 850, thus controlling dimension 820.

Resonant elements 205D are coupled to coaxial lines 805A, which extend through an opening in end plate 855. Coaxial lines 805A are gathered in a manner controlled by spreader 810A. Spreader 810A urges coaxial lines 805A apart while shorting ring 815A cinches coaxial lines 805A together. Spreader 810A, in one example, includes an insulative disk or other structure. Shorting ring 815A is electrically coupled to the shield conductor of coaxial lines 805A.

In one example, each resonant element is coupled to a transmit/receive switch, a transmitter, receiver or a transceiver. In one example, the connection includes a bundle of coaxial lines, each separately coupled by an electrical connection with a resonant element in the form of a transmission line.

In one example, the bundle of coaxial lines is gathered in a manner to provide a reflective end cap and at the same time serve as a sleeve balun. A sleeve balun does not transform the impedance and is coupled to the outer conductor of the coaxial line at a distance of approximately ¼λ (where λ represents the wavelength) from the feed point. The center conductor of the coaxial line is coupled to the resonant element by a matching capacitor connected in series. Each resonant element can be modeled as a ½λ antenna or transmission line.

In one example, a conductive shorting ring encircles the bundle of coaxial lines at a location ¼λ from the resonant elements. The shorting ring is electrically coupled to the outer (shield) conductor of the coaxial lines. Sheet currents present in the end cap region (between the shorting ring and the resonant elements) affect the coil performance. In particular, an additive B field effect is noticed in the end cap region. For example, by controlling the shape of the end cap (namely, adjusting the profile of the coaxial line path), the B field intensity is changed which results in changes to the homogeneity and therefore, the field of view. In one example, the field of view increases by converging the wire bundle at a point closer to the resonant elements. In one example, the profile of the coaxial line path is controlled by means of an insulative spreader disk located on the interior of the bundle. The spreader disk (bakelite, Teflon, Delrin for example) is coupled to each coaxial line by a plastic fastener or cable clamp.

At particular frequencies (for example low frequencies), the conductive shorting ring can be segmented and coupled using a capacitor (for example, 330 pF) to avoid gradient induced eddy currents.

The wire bundle structure serves as a sleeve balun in the region between the shorting ring and the resonant elements (to reduce any sheet currents) and serves as a reflective end-cap (to improve homogeneity) in the portion near the coil.

FIG. 9 illustrates bundle 900 having individual coaxial lines 805B spaced apart by spreader 810B and shorted by shorting ring 815B.

In some examples, parallel imaging performance is improved using a resonant element having a ground plane on three sides as illustrated in FIG. 1A. Such a ground plane provides improved element decoupling and improved coil sensitivity profiles. Gains in sensitivity and transmit efficiency for the adjustable array can be attributed to better coil-to-sample coupling and higher B1 sensitivity closer to the resonance elements. One example of the coil allows for flexibility in transmit phase and amplitude as well as excitation with, for instance, sixteen independent RF waveforms. This can be beneficial for controlling potentially destructive transmit phase interferences depending on coil size and coupling.

In one example, the frame includes a plurality of holders each of which are configured to carry a resonant element. Some of the holders may be individually or collectively repositionable as described herein. Resonant elements are coupled to the holders by mechanical fasteners (such as screws or rivets) or other structural features (such as shaped sections).

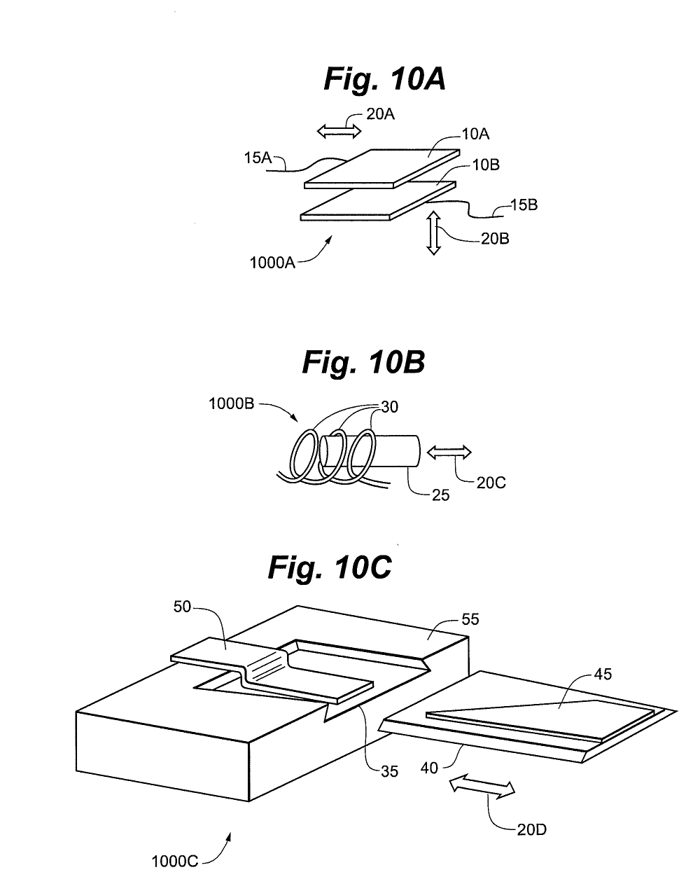

FIG. 10A illustrates a schematic of patch capacitor 1000A. Patch capacitor 1000A, also referred to as a decoupling capacitor, and includes conductive plates 10A and 10B separated by a dielectric. The dielectric can be air, a gas or other insulative material. Relative movement of plates 10A and 10B in the directions indicated by arrows 20B and 20A will affect the capacitance value. Conductive traces 15A and 15B provide electrical connections the resonant elements.

FIG. 10B illustrates a schematic of decoupling inductor 1000B. Inductor 1000B includes three windings 30 and core 25 disposed partially in the interior. Relative movement of windings 30 and core 25 in the direction indicated by arrow 20C will affect the inductive value.

FIG. 10C illustrates a view of exemplary patch capacitor 1000C. In the figure, insulative block 55 includes channel 35 configured to receive slide plate 40. Conductive foil 50 is adhesively bonded to a surface of channel 35. In addition, conductive foil 45 is adhesively bonded to a surface of slide plate 40. Relative movement of slide plate 40 and block 55 in the direction indicated by arrow 20D will affect the capacitance value. In one example, conductive foils 50 and 45 are electrically coupled to ground planes of adjacent resonant elements.

An exemplary capacitive patch includes a 2 mm thick dielectric substrate of 15 mm width coupled to a side of each resonant element. The dielectric substrate can include an insulative material such as a polymer (i.e. Teflon), glass or quartz. An adjacent dielectric substrate has a groove with corresponding dimensions to guide the 2 mm thick dielectric substrate and allow for variability based on the distance between adjacent resonant elements. An adhesive-backed copper tape (or foil) of 12 mm width disposed in the bottom of the groove is soldered to the output circuitry for each element as shown. The copper tape is configured in a manner to generate a capacitive function that correlates capacitance with coil size (namely, the spacing between adjacent resonant elements).

In one example, a capacitive patch includes a 2 mm thick Teflon substrate of 15 mm width attached to one side of a Teflon bar. The adjacent Teflon bar element includes a corresponding structure that guides the 2 mm Teflon patch and allows for variability depending on the distance between the resonant elements. An adhesive-backed copper tape of 12 mm width disposed in the bottom of the groove is soldered to the output circuitry for each resonant element as shown. The copper tape is configured in a manner to generate a capacitive function that matches the predetermined decoupling capacitor needs for various coil sizes. For example, a generally rectangular profile of copper tape will provide linear relationship between movement of the patch elements and capacitance. Other profiles that provide different functions are also contemplated, including triangular, segmented or curved foil shapes.

In other examples, the variable capacitor is configured to change spacing between conductive plates of a capacitor while the overlap (area) remains constant. In one example, a position of a dielectric is changed based on the position of the resonant elements, thus changing the coupling capacitance.

In one example, a variable inductance is configured to change inductance as a function of the distance between adjacent resonant elements. For example, inductance can be varied by inserting or withdrawing a core in the windings. As such, the resonant elements are coupled to a linkage that controls the position of a core relative to an inductor winding and thus, the coupling between the adjacent resonant elements can be changed. In one example, the space between adjacent windings, or loops, or the diameter of the windings of an inductor are varied to change the inductance as a function of distance between resonant elements. For example an inductor having flexible windings can be stretched or allowed to compress by a linkage coupled to the adjacent resonant elements, thus changing the inductance based on the resonant element spacing.

A system according to the present subject matter includes a coil as described herein as well as a processor or computer connected to the coil. The computer has a memory configured to execute instructions to control the coil and to generate magnetic resonance data. For example, the coil can be controlled to provide a particular RF phase, amplitude, pulse shape and timing to generate magnetic resonance data. The computer is coupled to a user-operable input device such as a keyboard, a memory, a mouse, a touch-screen or other input device for controlling the processor and thus, controlling the operation of the coil. In addition, the system includes an output device coupled to the processor. The output device is configured to generate a result as a function of the user selection. Exemplary output devices include a memory device, a display, a printer or a network connection. In one example, the frame of the coil is controlled by actuators driven by the processor. For example, a keyboard entry by a user can be configured to control the spacing of adjacent resonant elements.

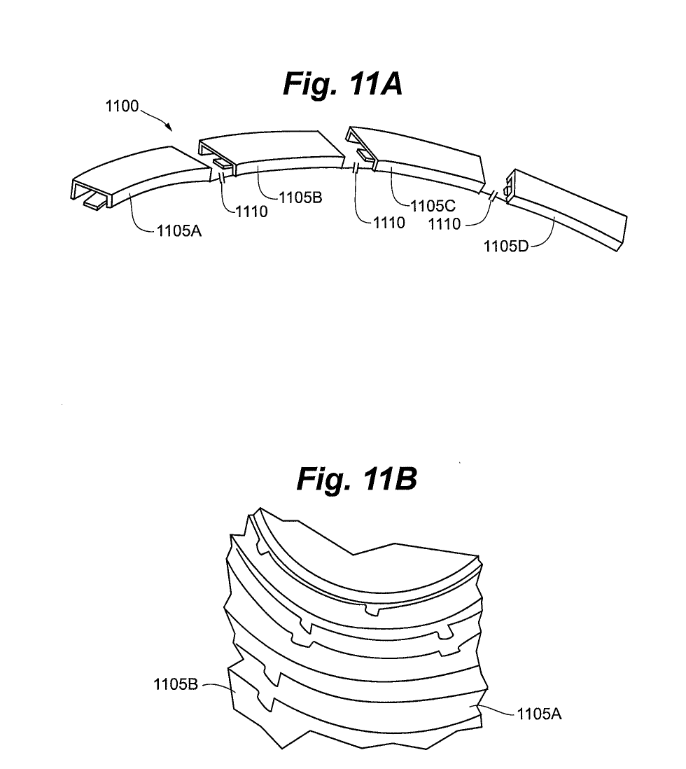

FIG. 11A illustrates row 1100 of resonant elements of a coil according to one example of the present subject matter. In the figure, row 1100 includes four discrete resonant elements 1105A, 1105B, 1105C and 1105D aligned end-to-end. Capacitor 1110 are electrically coupled between adjacent resonant elements. In one example, capacitors 1110 have a fixed value for a particular application. Each resonant element, such as 1105A, has a curved profile. In one example, the curvature is fixed and the angular alignment of the resonant element is determined by an adjusting screw or other structure. In one example, the resonant element is flexible and the curvature is determined by an adjusting screw or other structure. The dielectric for each resonant element illustrated is omitted in the figure for clarity and each resonant element is represented as a strip line conductor having a ground plane disposed on three sides and a strip inner conductor.

FIG. 11B illustrates one example of the resonant elements in FIG. 11A. In this example, each resonant element is seen mounted within the interior of a coil, with inner conductors disposed on top of a dielectric. In the illustrated example, two rings of discrete resonant elements are circumferentially disposed around the inside of a former. In one example, each ring contains 8 elements in which adjacent elements are electrically coupled by capacitors 1110, whereas in another example, adjacent resonant elements are geometrically decoupled. One element ring of FIG. 11B is mounted within the former at 7 cm from the top of the former, while the other element ring is mounted at 7 cm from bottom. In one example, the ring elements are mounted within another coil, such as the coil of FIG. 4.

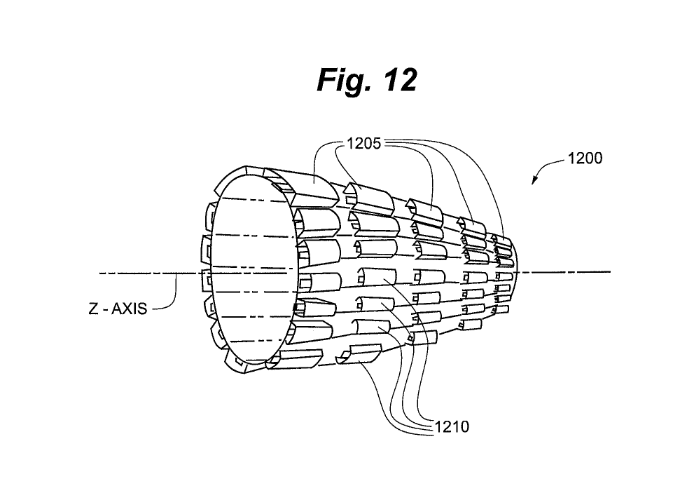

FIG. 12 includes volume coil 1200 having a curved profile relative to the z-axis. For example, coil 1200 can be configured for extremity imaging or for breast imaging. Resonant elements 1205 are aligned in a row, examples of which are shown in FIGS. 11A and 11B.

Resonant elements 1210 are aligned in a rank. The dielectric for each resonant element illustrated is omitted in the figure for clarity and each resonant element is represented as a strip line conductor having a ground plane disposed on three sides and a strip inner conductor. The resonant elements of coil 1200 can be of uniform size and configuration or of different size and configuration. For example, the resonant elements of a first rank can have a particular size and curvature that differs from those resonant elements of a second rank. The resonant elements of coil 1200 can be supported by an adjustable frame or coupling to a flexible material.

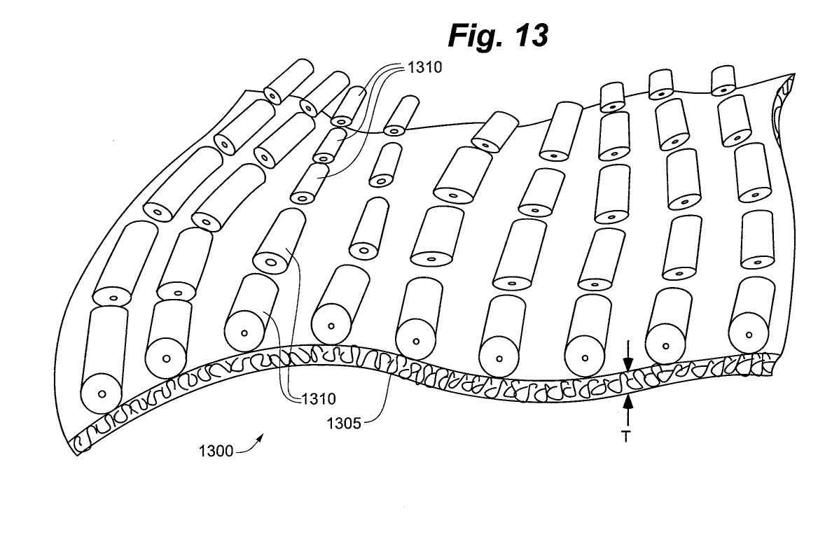

FIG. 13 includes segment 1300 of flexible material 1305 having a plurality of resonant elements 1310 mounted thereon. In the figure, resonant elements 1310 are aligned in rows with each resonant element in a row coupled together by an impedance element (omitted in the figure for clarity). The impedance element, such as capacitor 1110 of FIG. 11, can have a fixed or variable value. In addition, adjacent resonant elements can be coupled or decoupled together by a fixed or variable impedance element, as illustrated in FIG. 7.

The resonant elements are affixed to material 1305 by an adhesive bond or by mechanical fasteners. In one example, resonant elements 1310 are embedded in the thickness of material 1305. In one example, thickness T of material 1305 establishes a distance between the resonant element and the subject under study. A uniform thickness T facilitates uniform spacing. Resonant elements 1310 are illustrated as short coaxial line segments. In one example, material 1305 includes a fabric (woven or non-woven) or mesh of flexible fibers. In one example, material 1305 is a flexible plastic or polymer sheet. Material 1305 can be configured as a cylinder or a planer surface. In one example, coil 1300 includes a plurality of resonant elements and a fabric configured as a wearable garment such as a hat, a vest or a sleeve.

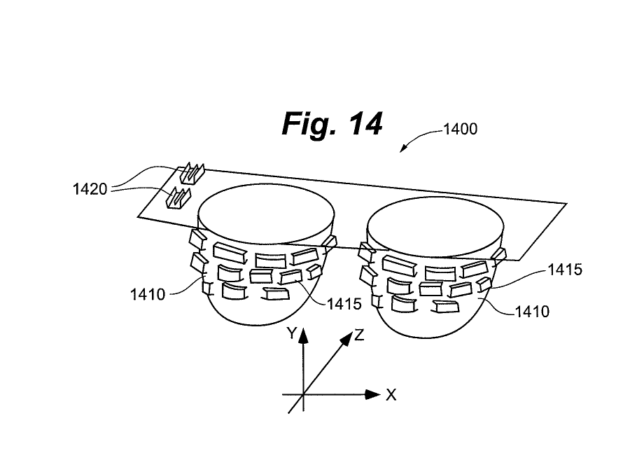

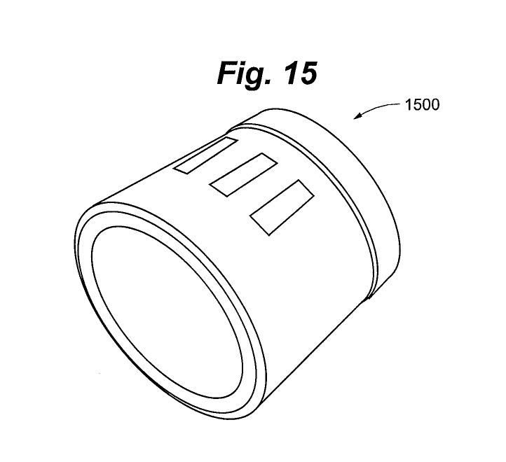

FIG. 14 includes breast coil 1400 according to another example of the present subject matter. Coil 1400 includes two breast cups 1410 having a plurality of resonant elements 1415 distributed about an exterior surface. Resonant elements 1415 are in rows about the y-axis and in various embodiments, are affixed to a mesh, fabric or other structure to hold the form illustrated. In addition, resonant elements 1420 are positioned in a manner sensitive to a particular target site. In the example illustrated, resonant elements 1420 are sensitive to the lymph node region on one side. Additional resonant elements and additional targeted areas can be provided. An array of more than two resonant elements, for example, at the lymph node site, is also contemplated. In one example, breast coil 1400 is fabricated of flexible material including foam. In one example, the resonant elements are embedded in foam or are flush with a surface of the foam.

FIG. 15 illustrates a housing 1500 which is capable of structurally supporting one or more coils. Specifically, the housing of FIG. 15 includes either a transmit, receive, or transmit/receive volume coil for magnetic resonance imaging of a subject's head. In one example, housing 1500 includes the multi-channel receive-only coil of FIG. 4, with the transmit-only coil of FIG. 5 disposed around the receive coil. In another example, ring elements, such as those in FIGS. 11A and 11B, which are mounted within the receive coil.

### CONCLUSION

It is to be understood that the above description is intended to be illustrative, and not restrictive. For example, the above-described embodiments (and/or aspects thereof) may be used in combination with each other. In addition, numbers (such as elements and channels), values (such as capacitance values, frequencies and physical dimensions) can be different than that provided in the examples herein. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The Abstract of the Disclosure is provided to comply with 37 C.F.R. § 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, various features may be grouped together to streamline the disclosure. This method of disclosure is not to be interpreted as reflecting an intention that the claimed embodiments require more features than are expressly recited in each claim. Rather, as the following claims reflect, inventive subject matter may lie in less than all features of a single disclosed embodiment. Thus, the following claims are hereby incorporated into the Detailed Description, with each claim standing on its own as a separate embodiment.

What is claimed is:

1. An extremity coil for Magnetic Resonance Imaging (MRI), the extremity coil comprising:
a transmit coil; and
a receive coil, the receive coil including a plurality of substantially planar loop elements disposed about a substantially tubular volume, at least one of the loop elements overlapping both a circumferentially adjacent loop element and an axially adjacent loop element.

2. The extremity coil of claim 1 wherein the plurality of substantially planar loop elements forms a substantially cylindrical array of loop elements.

3. The extremity coil of claim 2 wherein the cylindrical array is an 8-by-2 array of overlapping loop elements.

4. The extremity coil of claim 1 wherein at least one loop element is a different size than an axially adjacent loop element.

5. A Transmit Only Receive Only extremity coil for a Magnetic Resonance Imaging (MRI) system, comprising of: a transmit coil; and a receive coil array having a plurality of coils where the superior and inferior coils are displaced relative to each other on the first said direction, the anterior and inferior coils are displaced relative to each other on the second said direction and the left section and right section of coils are displaced relative to each other on the third said direction.

6. A Transmit Only Receive Only extremity coil in accordance with claim 5 wherein each of the plurality of coils of the receive coil array are configured as lattice-shaped coil elements.

7. A Transmit Only Receive Only extremity coil in accordance with claim 5 wherein each of the receiver coil arrays along the inferior and superior direction are geometrically overlapped.

8. A Transmit Only Receive Only extremity coil in accordance with claim 7, where each of the receive coil arrays along the anterior and posterior directions are isolated using inductively coupled solenoids.

9. A Transmit Only Receive Only extremity coil in accordance with claim 7, where each of the receive coil arrays along the anterior and posterior directions are isolated using pre-amplifiers for decoupling.

10. A Transmit Only Receive Only extremity coil in accordance with claim 7, where each of the receive coil arrays along the anterior and posterior directions are isolated using capacitive elements.

11. A Transmit Only Receive Only extremity coil in accordance with claim 7, where each of the receive coil arrays along the left section of the coils and the right section of the coils are isolated using inductively coupled solenoids.

12. A Transmit Only Receive Only extremity coil in accordance with claim 7, where each of the receive coil arrays along the left section of the coils and the right section of the coils are isolated using pre-amplifiers for decoupling.

13. A Transmit Only Receive Only extremity coil in accordance with claim 7, where each of the receive coil arrays along the left section of the coils and the right section of the coils are isolated using capacitive elements.

14. A Transmit Only Receive Only extremity coil in accordance with claim 5 wherein each of the receiver coil arrays along the inferior and superior direction and along the left section of the coils and the right section of the coils are geometrically overlapped.

15. A Transmit Only Receive Only extremity coil in accordance with claim 14 wherein each of the receiver coil arrays along the anterior and posterior directions are isolated using inductively coupled solenoids.

16. A Transmit Only Receive Only extremity coil in accordance with claim 14, where each of the receive coil arrays along the anterior and posterior directions are isolated using pre-amplifiers for decoupling.

17. A Transmit Only Receive Only extremity coil in accordance with claim 14, where each of the receive coil arrays along the anterior and posterior directions are isolated using capacitive elements.

18. A Transmit Only Receive Only coil in accordance with claim 5 wherein the transmit coil array comprising: a volume coil including a plurality of current elements, the volume coil for magnetic resonance having a regular or symmetric pattern or arrangement of current elements wherein each current element includes a transmission line segment having a first current path and a parallel return current path for the first current path, wherein, for each current element of the plurality of current elements the first current path is resonant with the parallel current return path.

19. A Transmit Only Receive Only coil in accordance with claim 18 wherein the transmit coil array comprising: a volume coil including a plurality of current elements, the volume coil for magnetic resonance having an aperture formed by removal or displacement of one or more current elements from a regular or symmetric pattern or arrangement of current elements wherein each current element includes a transmission line segment having a first current path and a parallel return current path for the first current path, wherein, for each current element of the plurality of current elements the first current path is resonant with the parallel current return path.

20. The apparatus of claim 18, wherein the remaining pattern or arrangement of current elements is capable of producing a desired field and the desired field is restored, compensated or otherwise effected by adjustment of currents in the plurality of current elements.

21. The apparatus of claim 19, wherein the remaining pattern or arrangement of current elements is capable of producing a desired field and the desired field is restored, compensated or otherwise effected by adjustment of currents in the plurality of current elements.

22. The apparatus of claim 19, wherein the volume coil includes a top and one or more of the regular or symmetric pattern or arrangement of current elements is removed from the top for improved access from the top and the desired field is restored.

23. The apparatus of claim 18, wherein the volume coil includes two open ends.

24. The apparatus of claim 19, wherein the volume coil includes two open ends.

25. The apparatus of claim 18, wherein the volume coil is capable of being used in extremity imaging.

26. The apparatus of claim 18, wherein the volume coil is capable of being used in extremity imaging.

27. The apparatus of claim 20, wherein the volume coil includes an impedance and the impedance is adjusted to control current in the plurality of current elements.

28. The apparatus of claim 21, wherein the volume coil includes an impedance and the impedance is adjusted to control current in the plurality of current elements.

29. The apparatus of claim 20, wherein the impedance is adjusted by adjusting a capacitance.

30. The apparatus of claim 21, wherein the impedance is adjusted by adjusting a capacitance.

31. The apparatus of claim 20, wherein the impedance is adjusted by adjusting an inductance.

32. The apparatus of claim 20, wherein the impedance is adjusted by adjusting an inductance.

33. The apparatus of claim 20, further comprising a radio frequency conductive front end ring coupled to the plurality of current elements and a radio frequency conductive back end ring coupled to the plurality of current elements.

34. The apparatus of claim 21, further comprising a radio frequency conductive front end ring including a gap and a radio frequency conductive back end ring including a gap, the radio frequency conductive front end ring and the radio frequency conductive back end ring coupled to the plurality of radio frequency current elements.

35. The apparatus of claim 21, further comprising a slotted shield or cavity wall coupled to the plurality of radio frequency current elements.

36. The apparatus of claim 21, further comprising a slotted shield or cavity wall coupled to the plurality of radio frequency current elements.

37. The apparatus of claim 20, further comprising means to actively detune/retune the volume coil for use with a local receiver coil.

38. The apparatus of claim 21, further comprising means to actively detune/retune the volume coil for use with a local receiver coil.

39. A Transmit Only Receive Only coil in accordance with claim 5 wherein the transmit coil array comprises a circularly polarized birdcage coil.

40. A magnetic resonance imaging (MRI) system comprising:
an annular vacuum chamber which defines a cylindrical inner bore therein;
an annular helium reservoir disposed within the vacuum chamber surrounding and displaced from the central bore thereof;
a superconducting primary magnetic field coil disposed within the helium chamber for generating a substantially uniform magnetic field longitudinally through the central bore;
a self-shielded gradient coil assembly disposed in the central bore for generating gradient magnetic fields across a central region thereof and for shielding the vacuum chamber, the helium reservoir, and other components within the vacuum chamber from the generated gradient field magnetic fields such that eddy currents are not induced in the vacuum chamber or the contained associated structure;
A Transmit Only Receive Only extremity coil for a Magnetic Resonance Imaging (MRI) system, comprising of: a transmit coil; and a receive coil array having a plurality of coils where the superior and inferior coils are displaced relative to each other on the first said direction, the anterior and inferior coils are displaced relative to each other on the second said direction and the left section and right section of coils are displaced relative to each other on the third said direction
a scan control which selectively causes electrical pulses to be applied to the x, y, and z-primary and shield gradient coils;
a radio frequency transmitter which applies radio frequency pulses to the radio frequency Transmit Only coil for exciting and manipulating magnetic resonance of selected dipoles within the examination region;
a receiver which receives and demodulates magnetic resonance signals emanating from the plurality of the Receive Only coil arrays located on the examination region; and
a reconstruction processor which reconstructs the demodulated magnetic resonance signals into an image representation.

41. The MRI system of claim 40 wherein the transmit and receive coil arrays are configured to image human extremities.

42. The MRI system of claim 40 wherein the superior and inferior coils are configured to provide different imaging field-of-views.

43. The MRI system of claim 40 wherein the length of the transmit only coil is longer than the overall length of the receive only array.

44. The MRI system of claim 40 wherein the length of the transmit only coil is smaller than the overall length of the receive only array.
